(19) United States
(12) Patent Application Publication
(10) Pub. No.: US 2024/0007082 A1
(43) Pub. Date: Jan. 4, 2024

(54) ACOUSTIC WAVE DEVICE AND METHOD FOR MANUFACTURING ACOUSTIC WAVE DEVICE

(71) Applicant: Murata Manufacturing Co., Ltd., Nagaokakyo-shi (JP)

(72) Inventors: Kazunori INOUE, Nagaokakyo-shi (JP); Seiji KAI, Nagaokakyo-shi (JP)

(21) Appl. No.: 18/369,899

(22) Filed: Sep. 19, 2023

Related U.S. Application Data
(63) Continuation of application No. PCT/JP2022/016877, filed on Mar. 31, 2022.
(60) Provisional application No. 63/168,334, filed on Mar. 31, 2021.

(51) Int. Cl. H03H 9/17; H03H 3/02; H03H 9/02; H03H 9/13

(52) U.S. Cl. CPC H03H 9/17; H03H 3/02; H03H 2003/021; H03H 9/132; H03H 9/02157; H03H 9/02015

(57) ABSTRACT

An acoustic wave device includes a first substrate, a piezoelectric layer adjacent to a first principal surface of the first substrate, a functional electrode on the piezoelectric layer, a second substrate, and a third substrate. The second substrate is adjacent to the first principal surface of the first substrate and faces the first substrate, with a second hollow interposed therebetween. The third substrate is adjacent to a second principal surface of the first substrate and faces the first substrate, with a first hollow interposed therebetween. The acoustic wave device includes a first support portion between the first principal surface of the first substrate and the second substrate, and a second support portion between the first substrate and the third substrate.

### CROSS REFERENCE TO RELATED APPLICATIONS

This application claims the benefit of priority to Provisional Patent Application No. 63/168,334 filed on Mar. 31, 2021 and is a Continuation Application of PCT Application No. PCT/JP2022/016877 filed on Mar. 31, 2022. The entire contents of each application are hereby incorporated herein by reference.

### BACKGROUND OF THE INVENTION

### 1. Field of the Invention

The present disclosure relates to an acoustic wave device and a method for manufacturing an acoustic wave device.

### 2. Description of the Related Art

Japanese Unexamined Patent Application Publication No. 2012-257019 describes an acoustic wave device.

### SUMMARY OF THE INVENTION

When, in Japanese Unexamined Patent Application Publication No. 2012-257019, a support that supports a piezoelectric layer is made thinner, the mechanical strength of the support is more likely to be degraded.

Preferred embodiments of the present invention each make a support supporting a piezoelectric layer thinner and, at the same time, reduce degradation of the mechanical strength of the support.

An acoustic wave device according to a preferred embodiment includes a first substrate with a thickness in a first direction and including a first principal surface and a second principal surface opposite the first principal surface, a piezoelectric layer adjacent to the first principal surface of the first substrate, a functional electrode on the piezoelectric layer, a first hollow of the first substrate overlapping at least portion of the functional electrode as viewed in the first direction, a second substrate adjacent to the first principal surface of the first substrate and facing the first substrate with a second hollow interposed therebetween, a first support portion between the first principal surface of the first substrate and the second substrate, a third substrate adjacent to the second principal surface of the first substrate and facing the first substrate with the first hollow interposed therebetween, and a second support portion between the first substrate and the third substrate.

A method for manufacturing an acoustic wave device according to a preferred embodiment includes a support forming step of forming a support including a first substrate with a thickness in a first direction and including a first principal surface and a second principal surface opposite the first principal surface, a piezoelectric layer adjacent to the first principal surface of the first substrate, and a functional electrode on the piezoelectric layer, a first joining step of, after the support forming step, placing a second substrate adjacent to the first principal surface of the first substrate, with a second hollow therebetween, and joining the second substrate to the support, with a first support portion therebetween, and a thinning step of, after the first joining step, making the first substrate thinner.

Preferred embodiments of the present disclosure make a support supporting a piezoelectric layer thinner and, at the same time, reduce or prevent degradation of the mechanical strength of the support.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1A is a perspective view of an acoustic wave device according to the present preferred embodiment of the present invention.

FIG. 1B is a plan view of an electrode structure according to the present preferred embodiment of the present invention.

FIG. 2 is a cross-sectional view taken along line II-II of FIG. 1A.

FIG. 3A is a schematic cross-sectional view for explaining Lamb waves propagating in a piezoelectric layer of Comparative Example.

FIG. 3B is a schematic cross-sectional view for explaining first-order thickness shear mode bulk waves propagating in a piezoelectric layer of the present preferred embodiment of the present invention.

FIG. 4 is a schematic cross-sectional view for explaining an amplitude direction of first-order thickness shear mode bulk waves propagating in the piezoelectric layer of the present preferred embodiment of the present invention.

FIG. 5 is an explanatory diagram illustrating an example of resonance characteristics of the acoustic wave device according to the present preferred embodiment of the present invention.

FIG. 6 is an explanatory diagram illustrating a relation between d/2p and a fractional bandwidth of the acoustic wave device of the present preferred embodiment serving as a resonator, where p is a center-to-center distance or average center-to-center distance between adjacent electrodes and d is an average thickness of the piezoelectric layer.

FIG. 7 is a plan view illustrating an example of one electrode pair in an acoustic wave device according to the present preferred embodiment of the present invention.

FIG. 8 is a reference diagram illustrating an example of resonance characteristics of the acoustic wave device according to the present preferred embodiment of the present invention.

FIG. 9 is an explanatory diagram illustrating a relation between the fractional bandwidth of the acoustic wave device of the present preferred embodiment of the present invention, and the amount of phase rotation of impedance of spurious emission normalized at 180 degrees to represent the level of spurious emission.

FIG. 10 is an explanatory diagram illustrating a relation between d/2p, metallization ratio MR, and fractional bandwidth.

FIG. 11 is an explanatory diagram illustrating a map of fractional bandwidth with respect to Euler angles (0°, θ, Ψ) of LiNbO₃ obtained when d/p is as close as possible to 0.

FIG. 12 is a partial cutaway perspective view for explaining an acoustic wave device according to the present preferred embodiment of the present invention.

FIG. 13 is a plan view of a first cover according to a first preferred embodiment of the present invention, as viewed from a first principal surface thereof.

FIG. 14 is a plan view of the first cover according to the first preferred embodiment of the present invention, as viewed from a second principal surface thereof.

FIG. 15 is a plan view of an acoustic wave element substrate according to the first preferred embodiment of the present invention, as viewed from a first principal surface thereof.

FIG. 16 is a plan view of the acoustic wave element substrate according to the first preferred embodiment of the present invention, as viewed from a second principal surface thereof.

FIG. 17 is a plan view of a second cover according to the first preferred embodiment of the present invention, as viewed from a first principal surface thereof.

FIG. 18 is a plan view of the second cover according to the first preferred embodiment of the present invention, as viewed from a second principal surface thereof.

FIG. 19 is a schematic cross-sectional view illustrating a cross section taken along line XIX-XIX of FIG. 13 to FIG. 18.

FIG. 20 is a schematic cross-sectional view for explaining a support forming step of forming the acoustic wave element substrate according to the first preferred embodiment of the present invention.

FIG. 21 is a schematic cross-sectional view for explaining a dielectric film forming step of forming a dielectric film on the acoustic wave element substrate according to the first preferred embodiment of the present invention.

FIG. 22A is a schematic cross-sectional view for explaining a first cover forming step of forming the first cover according to the first preferred embodiment of the present invention.

FIG. 22B is a schematic cross-sectional view for explaining a second cover forming step of forming the second cover according to the first preferred embodiment of the present invention.

FIG. 23 is a schematic cross-sectional view for explaining a first joining step of joining the first cover to the acoustic wave element substrate.

FIG. 24 is a schematic cross-sectional view for explaining a thinning step of making a first substrate thinner according to the first preferred embodiment of the present invention.

FIG. 25 is a schematic cross-sectional view for explaining a first hollow forming step of forming a first hollow in the first substrate according to the first preferred embodiment of the present invention.

FIG. 26 is a schematic cross-sectional view for explaining a wire forming step of forming an extended electrode on a second principal surface of the first substrate according to the first preferred embodiment of the present invention.

FIG. 27 is a schematic cross-sectional view for explaining a wire forming step of forming a dielectric film on a second principal surface of the first substrate according to the first preferred embodiment of the present invention.

FIG. 28 is a schematic cross-sectional view for explaining a frequency adjusting step of adjusting the frequency of the acoustic wave device according to the first preferred embodiment of the present invention.

FIG. 29 is a schematic cross-sectional view for explaining a joint metal forming step of forming a joining layer on the second principal surface of the first substrate according to the first preferred embodiment of the present invention.

FIG. 30 is a schematic cross-sectional view for explaining a second joining step of joining the second cover to the acoustic wave element substrate.

FIG. 31 is a schematic cross-sectional view for explaining a thinning step of making a third substrate thinner according to the first preferred embodiment of the present invention.

FIG. 32 is a schematic cross-sectional view for explaining a through via forming step of forming a through via in the third substrate according to the first preferred embodiment of the present invention.

FIG. 33 is a schematic cross-sectional view for explaining a seed metal layer forming step of forming a seed metal layer adjacent to a second principal surface of the third substrate according to the first preferred embodiment of the present invention.

FIG. 34 is a schematic cross-sectional view for explaining a terminal electrode forming step of forming a terminal electrode adjacent to the second principal surface of the third substrate according to the first preferred embodiment of the present invention.

### DETAILED DESCRIPTION OF THE PREFERRED EMBODIMENTS

Preferred embodiments of the present disclosure will now be described in detail on the basis of the drawings. Note that the preferred embodiments described below do not limit the present disclosure. The preferred embodiments of the present disclosure are presented for illustrative purposes. In modifications and second and other preferred embodiments that follow, where some components of different preferred embodiments can be replaced or combined, the description of matters common to the first preferred embodiment will be omitted and differences alone will be described. In particular, the same operations and effects achieved by the same configurations will not be mentioned in the description of each preferred embodiment.

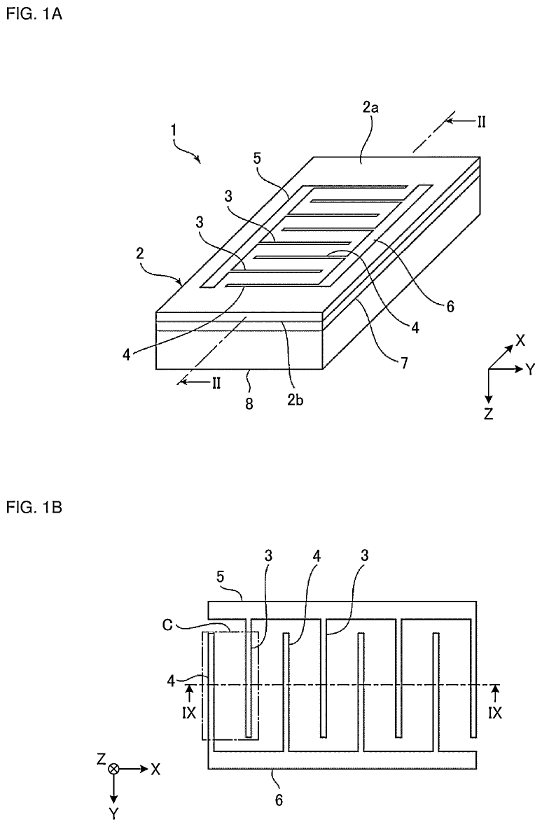

FIG. 1A is a perspective view of an acoustic wave device according to the present preferred embodiment. FIG. 1B is a plan view of an electrode structure according to the present preferred embodiment.

An acoustic wave device 1 according to the present preferred embodiment includes a piezoelectric layer 2 made of LiNbO₃. The piezoelectric layer 2 may be made of LiTaO₃. The cut-angles of LiNbO₃ and LiTaO₃ are Z-cut in the present preferred embodiment. The cut-angles of LiNbO₃ and LiTaO₃ may be rotated Y-cut or X-cut. It is preferable that the propagation orientation be Y-propagation and X-propagation±about 30°, for example.

The thickness of the piezoelectric layer 2 is not particularly limited. For effective excitation of first-order thickness shear mode, the thickness of the piezoelectric layer 2 is preferably greater than or equal to about 50 nm and less than or equal to about 1000 nm, for example.

The piezoelectric layer 2 includes a first principal surface 2a and a second principal surface 2b opposite each other in the Z direction. Electrode fingers 3 and 4 are arranged on the first principal surface 2a.

Here, the electrode finger 3 is an example of “first electrode finger”, and the electrode finger 4 is an example of “second electrode finger”. In FIG. 1A and FIG. 1B, a plurality of electrode fingers 3 are a plurality of “first electrode fingers” connected to a first busbar electrode 5, and a plurality of electrode fingers 4 are a plurality of “second electrode fingers” connected to a second busbar electrode 6. The plurality of electrode fingers 3 and the plurality of electrode fingers 4 are interdigitated with each other. The electrode fingers 3, the electrode fingers 4, the first busbar electrode 5, and the second busbar electrode 6 thus define a functional electrode 30. The functional electrode 30 is also referred to as an interdigital transducer (IDT) electrode 30.

The electrode fingers 3 and 4 are rectangular in shape and have a length direction. In a direction orthogonal to the length direction, adjacent ones of the electrode fingers 3 and 4 face each other. Both the length direction of the electrode fingers 3 and 4 and the direction orthogonal to the length direction of the electrode fingers 3 and 4 are directions that cross the thickness direction of the piezoelectric layer 2. Therefore, adjacent ones of the electrode fingers 3 and 4 can also be considered facing each other in the direction crossing the thickness direction of the piezoelectric layer 2. Hereinafter, the thickness direction of the piezoelectric layer 2 may be described as a Z direction (or first direction), the length direction of the electrode fingers 3 and 4 may be described as a Y direction (or second direction), and the direction orthogonal to the electrode fingers 3 and 4 may be described as an X direction (or third direction).

The length direction of the electrode fingers 3 and 4 may be interchanged with the direction orthogonal to the length direction of the electrode fingers 3 and 4 illustrated in FIG. 1A and FIG. 1B. That is, the electrode fingers 3 and 4 may extend in the direction in which the first busbar electrode 5 and the second busbar electrode 6 extend in FIG. 1A and FIG. 1B. In this case, the first busbar electrode 5 and the second busbar electrode 6 extend in the direction in which the electrode fingers 3 and 4 extend in FIG. 1A and FIG. 1B. A plurality of pairs of adjacent electrode fingers 3 and 4, the electrode finger 3 being connected to one potential and the electrode finger 4 being connected to the other potential, are arranged in the direction orthogonal to the length direction of the electrode fingers 3 and 4.

Here, the electrode fingers 3 and 4 adjacent to each other are not in direct contact, but are spaced from each other. The electrode fingers 3 and 4 adjacent to each other are not provided with other electrodes (including other electrode fingers 3 and 4) therebetween connected to hot and ground electrodes. The number of pairs of adjacent electrode fingers 3 and 4 does not necessarily need to be an integer, and there may be, for example, 1.5 pairs or 2.5 pairs.

A center-to-center distance, or pitch, between the electrode fingers 3 and 4 is preferably greater than or equal to 1 μm and less than or equal to about 10 μm, for example. The center-to-center distance between the electrode fingers 3 and 4 is a distance from the center of the width dimension of the electrode finger 3 in the direction orthogonal to the length direction of the electrode finger 3 to the center of the width dimension of the electrode finger 4 in the direction orthogonal to the length direction of the electrode finger 4.

When the electrode fingers 3 and 4 include at least a plurality of electrode fingers 3 or a plurality of electrode fingers 4 (i.e., there are greater than or equal to 1.5 electrode pairs, each including the electrode finger 3 and the electrode finger 4), the center-to-center distance between the electrode fingers 3 and 4 is the average of the center-to-center distances between adjacent ones of the greater than or equal to 1.5 pairs of electrode fingers 3 and 4.

The width of the electrode fingers 3 and 4, or the dimension of the electrode fingers 3 and 4 in the direction in which the electrode fingers 3 and 4 face each other, is preferably greater than or equal to about 150 nm and less than or equal to about 1000 nm, for example. The center-to-center distance between the electrode fingers 3 and 4 is a distance from the center of the dimension (width dimension) of the electrode finger 3 in the direction orthogonal to the length direction of the electrode finger 3 to the center of the dimension (width dimension) of the electrode finger 4 in the direction orthogonal to the length direction of the electrode finger 4.

In the present preferred embodiment, where a Z-cut piezoelectric layer is used, the direction orthogonal to the length direction of the electrode fingers 3 and 4 is a direction orthogonal to the polarization direction of the piezoelectric layer 2. This is not applicable when a piezoelectric body with other cut-angles is used as the piezoelectric layer 2. Here, the term “orthogonal” may refer not only to being exactly orthogonal, but also to being substantially orthogonal (e.g., the angle between the direction orthogonal to the length direction of the electrode fingers 3 and 4 and the polarization direction is about 90°±10°, for example).

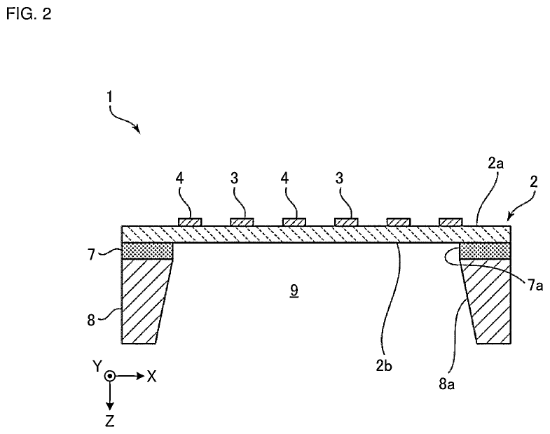

A support substrate 8 is disposed adjacent to the second principal surface 2b of the piezoelectric layer 2, with an intermediate layer 7 interposed therebetween. The intermediate layer 7 and the support substrate 8 have a frame shape. As illustrated in FIG. 2, the intermediate layer 7 and the support substrate 8 are provided with cavities 7a and 8a, respectively, which define a hollow (air gap) 9.

The hollow 9 is provided to allow vibration of an excitation region C of the piezoelectric layer 2. Therefore, the support substrate 8 is disposed adjacent to the second principal surface 2b, with the intermediate layer 7 interposed therebetween, so as not to overlap at least one pair of electrode fingers 3 and 4. The intermediate layer 7 is optional. That is, the support substrate 8 may be disposed on the second principal surface 2b of the piezoelectric layer 2, either directly or indirectly.

The intermediate layer 7 is made of silicon oxide. The intermediate layer 7 can be made of an appropriate insulating material, such as silicon nitride or alumina, other than silicon oxide. The intermediate layer 7 is an example of “intermediate layer”.

The support substrate 8 is made of Si. The plane orientation of the Si substrate on the surface thereof adjacent to the piezoelectric layer 2 may be (100), (110), or (111). It is preferable that the Si be a high-resistance Si with a resistivity of greater than or equal to about 4 kΩ, for example. The support substrate 8 can also be made of an appropriate insulating material or semiconductor material. Examples of the material used to form the support substrate 8 include piezoelectric materials, such as aluminum oxide, lithium tantalate, lithium niobate, and crystals; various ceramics, such as alumina, magnesia, sapphire, silicon nitride, aluminum nitride, silicon carbide, zirconia, cordierite, mullite, steatite, and forsterite; dielectrics, such as diamond and glass; and a semiconductor, such as gallium nitride.

The plurality of electrode fingers 3 and 4, the first busbar electrode 5, and the second busbar electrode 6 are made of an appropriate metal, such as Al, or an appropriate alloy, such as AlCu alloy. In the present preferred embodiment, the electrode fingers 3 and 4, the first busbar electrode 5, and the second busbar electrode 6 have a multilayer structure of a Ti film and an Al film on the Ti film. The Ti film may be replaced by a different adhesion layer.

To drive the acoustic wave device 1, an alternating-current voltage is applied between the plurality of electrode fingers 3 and the plurality of electrode fingers 4. More specifically, an alternating-current voltage is applied between the first busbar electrode 5 and the second busbar electrode 6. This can produce resonance characteristics using first-order thickness shear mode bulk waves excited in the piezoelectric layer 2.

In the acoustic wave device 1, d/p is less than or equal to about 0.5, for example, where d is the thickness of the piezoelectric layer 2 and p is the center-to-center distance between any adjacent electrode fingers 3 and 4 of the plurality of pairs of electrode fingers 3 and 4. This allows effective excitation of the first-order thickness shear mode bulk waves and can produce good resonance characteristics. It is more preferable that d/p be less than or equal to about 0.24, for example. This produces better resonance characteristics.

As in the present preferred embodiment, when the electrode fingers 3 and 4 include at least a plurality of electrode fingers 3 or a plurality of electrode fingers 4 (i.e., there are greater than or equal to 1.5 electrode pairs, each including the electrode finger 3 and the electrode finger 4), the center-to-center distance p between the adjacent electrode fingers 3 and 4 is the average center-to-center distance between all adjacent electrode fingers 3 and 4.

In the acoustic wave device 1 of the present preferred embodiment configured as described above, the Q factor does not decrease easily even if the number of pairs of the electrode fingers 3 and 4 is reduced for the purpose of size reduction. This is because the acoustic wave device 1 is a resonator that does not require reflectors on both sides, and thus does not suffer significant propagation loss. The acoustic wave device 1 does not require reflectors, because it uses first-order thickness shear mode bulk waves.

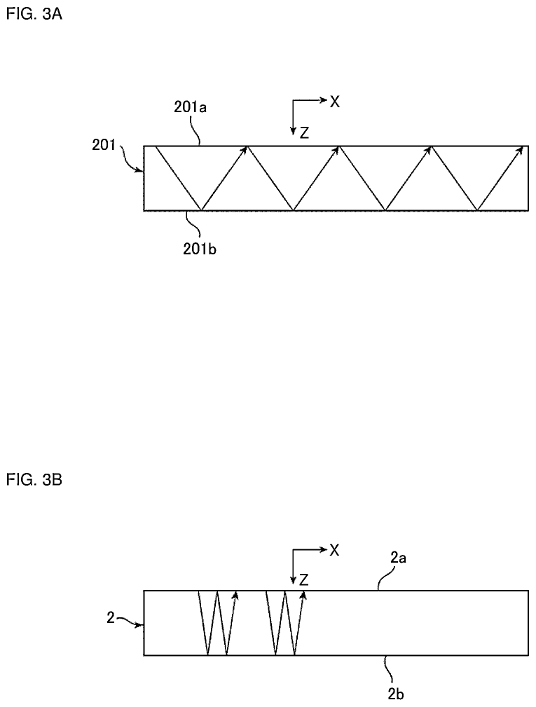

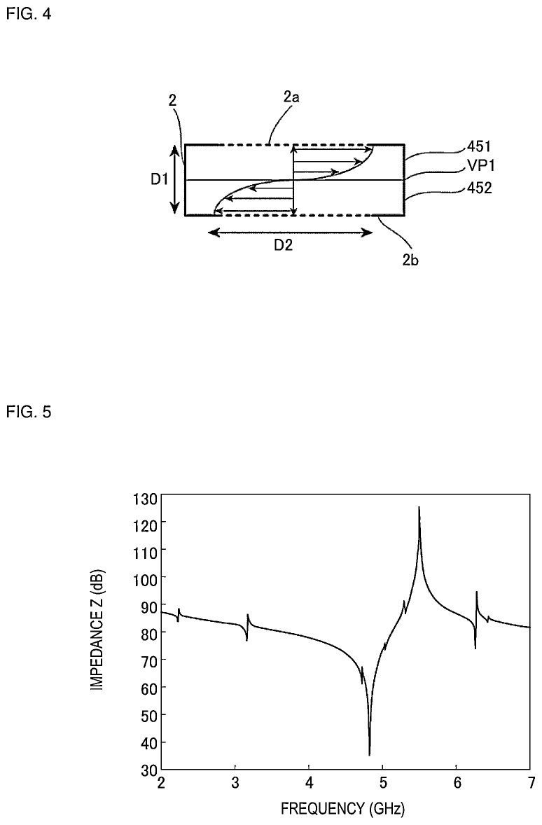

FIG. 3A is a schematic cross-sectional view for explaining Lamb waves propagating in a piezoelectric layer of Comparative Example. FIG. 3B is a schematic cross-sectional view for explaining first-order thickness shear mode bulk waves propagating in the piezoelectric layer of the present preferred embodiment. FIG. 4 is a schematic cross-sectional view for explaining an amplitude direction of first-order thickness shear mode bulk waves propagating in the piezoelectric layer of the present preferred embodiment.

FIG. 3A illustrates Lamb waves propagating in a piezoelectric layer of an acoustic wave device, such as that described in Japanese Unexamined Patent Application Publication No. 2012-257019. As illustrated in FIG. 3A, the waves propagate in a piezoelectric layer 201 as indicated by arrows. The piezoelectric layer 201 includes a first principal surface 201a and a second principal surface 201b. A thickness direction, which connects the first principal surface 201a and the second principal surface 201b, is the Z direction. The X direction is a direction in which the electrode fingers 3 and 4 of the functional electrode 30 are arranged. The Lamb waves propagate in the X direction, as illustrated in FIG. 3A. Although the entire piezoelectric layer 201 vibrates, the Lamb waves (plate waves) propagate in the X direction. Reflectors are thus provided on both sides to produce resonance characteristics. This causes wave propagation loss and results in a low Q factor when the number of pairs of the electrode fingers 3 and 4 is reduced for size reduction.

In the acoustic wave device of the present preferred embodiment, as illustrated in FIG. 3B, vibration displacement takes place in the thickness shear direction. Therefore, the waves propagate substantially in the direction connecting the first principal surface 2a and the second principal surface 2b of the piezoelectric layer 2, that is, substantially in the Z direction, and resonate. In other words, the X direction component of the waves is much smaller than the Z direction component of the waves. Since the wave propagation in the Z direction produces resonance characteristics, the acoustic wave device requires no reflectors. This prevents propagation loss that occurs during propagation to reflectors. Therefore, the Q factor does not decrease easily even if the number of electrode pairs, each including the electrode fingers 3 and 4, is reduced for the purpose of size reduction.

As illustrated in FIG. 4, the amplitude direction of first-order thickness shear mode bulk waves in a first region 451 included in the excitation region C (see FIG. 1B) of the piezoelectric layer 2 is opposite that in a second region 452 included in the excitation region C. FIG. 4 schematically illustrates how bulk waves behave when a voltage that makes the potential of the electrode finger 4 higher than that of the electrode finger 3 is applied between the electrode fingers 3 and 4. In the excitation region C, the first region 451 is a region between a virtual plane VP1 and the first principal surface 2a, and the second region 452 is a region between the virtual plane VP1 and the second principal surface 2b. The virtual plane VP1 is orthogonal to the thickness direction of the piezoelectric layer 2 and divides the piezoelectric layer 2 into two.

The acoustic wave device 1 includes at least one electrode pair including the electrode fingers 3 and 4. Since the acoustic wave device 1 is not configured to propagate waves in the X direction, it is not necessarily required that there be more than one electrode pair including the electrode fingers 3 and 4. That is, the acoustic wave device 1 simply requires at least one electrode pair.

For example, the electrode finger 3 is an electrode connected to the hot potential, and the electrode finger 4 is an electrode connected to the ground potential. Alternatively, the electrode finger 3 and the electrode finger 4 may be connected to the ground potential and the hot potential, respectively. In the present preferred embodiment, the at least one electrode pair is a combination of electrodes, one connected to the hot potential and the other connected to the ground potential, as described above, and no floating electrode is provided.

FIG. 5 is an explanatory diagram illustrating an example of resonance characteristics of the acoustic wave device according to the present preferred embodiment. The design parameters of an example of the acoustic wave device 1 having the resonance characteristics illustrated in FIG. 5 are as follows.
Piezoelectric layer 2: LiNbO₃ with Euler angles (0°, 0°, 90°)
Thickness of piezoelectric layer 2: 400 nm
Length of excitation region C (see FIG. 1B): 40 μm
Number of electrode pairs, each including electrode fingers 3 and 4: 21 pairs
Center-to-center distance (pitch) between electrode fingers 3 and 4: 3 μm
Width of electrode fingers 3 and 4: 500 nm
d/p: 0.133
Intermediate layer 7: 1 μm-thick silicon oxide film
Support substrate 8: Si

The excitation region C (see FIG. 1B) is a region where the electrode fingers 3 and 4 overlap, as viewed in the X direction orthogonal to the length direction of the electrode fingers 3 and 4. The length of the excitation region C is a dimension of the excitation region C along the length direction of the electrode fingers 3 and 4. The excitation region C is an example of “overlap region”.

In the present preferred embodiment, all electrode pairs, each including the electrode fingers 3 and 4, have the same interelectrode distance. That is, the electrode fingers 3 and 4 are arranged with an equal pitch.

As is clear from FIG. 5, good resonance characteristics with a fractional bandwidth of about 12.5% are obtained without reflectors, for example.

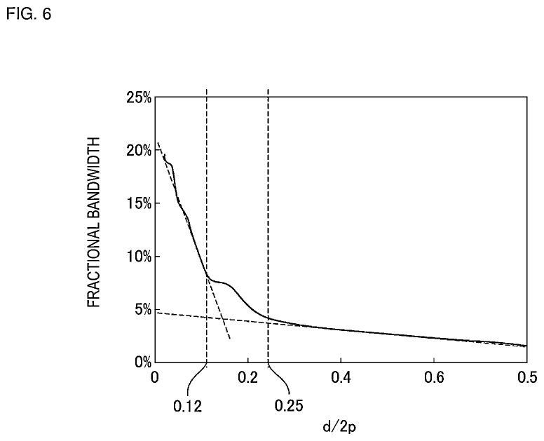

In the present preferred embodiment, d/p is less than or equal to about 0.5 and more preferably less than or equal to about 0.24, for example, where d is the thickness of the piezoelectric layer 2 and p is the center-to-center distance between the electrode fingers 3 and 4. This will now be described with reference to FIG. 6.

A plurality of acoustic wave devices are produced by varying d/2p of the acoustic wave device having the resonance characteristics illustrated in FIG. 5. FIG. 6 is an explanatory diagram illustrating a relation between d/2p and a fractional bandwidth of the acoustic wave device of the present preferred embodiment serving as a resonator, where p is the center-to-center distance between adjacent electrodes or the average center-to-center distance between adjacent electrodes, and d is the average thickness of the piezoelectric layer 2.

As illustrated in FIG. 6, if d/2p exceeds about 0.25 (or d/p>about 0.5), the fractional bandwidth falls below about 5% even when d/p is adjusted, for example. On the other hand, if d/2p≤about 0.25 (or d/p≤about 0.5) is satisfied, the fractional bandwidth can be made greater than or equal to about 5% by varying d/p within the range, for example, that is, a resonator having a high coupling coefficient can be obtained. If d/2p is less than or equal to about 0.12, that is, if d/p is less than or equal to about 0.24, for example, the fractional bandwidth can be made as high as about 7% or more, for example. Additionally, by adjusting d/p within this range, a resonator with a wider fractional bandwidth and a higher coupling coefficient can be produced. Thus, by making d/p less than or equal to about 0.5, for example, a resonator with a higher coupling coefficient using first-order thickness shear mode bulk waves can be obtained.

It is simply required that there be at least one electrode pair. In the case of one electrode pair, p is the center-to-center distance between adjacent electrode fingers 3 and 4. In the case of greater than or equal to 1.5 electrode pairs, p may be the average center-to-center distance between adjacent electrode fingers 3 and 4.

If the piezoelectric layer 2 varies in thickness, the average thickness of the piezoelectric layer 2 may be used as the thickness d of the piezoelectric layer 2.

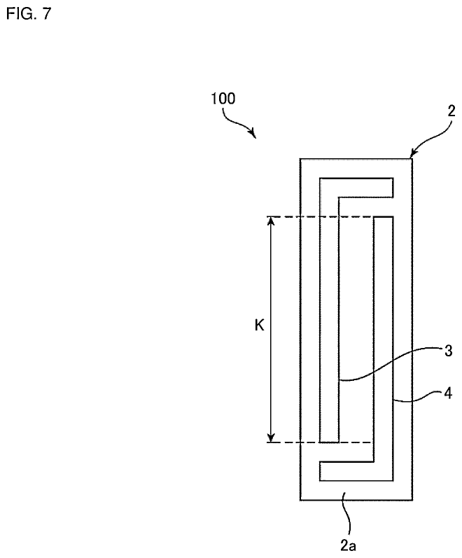

FIG. 7 is a plan view illustrating an example of one electrode pair in an acoustic wave device according to the present preferred embodiment. An acoustic wave device 101 includes one electrode pair including the electrode fingers 3 and 4 on the first principal surface 2a of the piezoelectric layer 2. Note that K in FIG. 7 indicates an overlap width. As described above, the acoustic wave device according to the present disclosure may include only one electrode pair. Even in this case, the first-order thickness shear mode bulk waves can be effectively excited if d/p is less than or equal to about 0.5, for example.

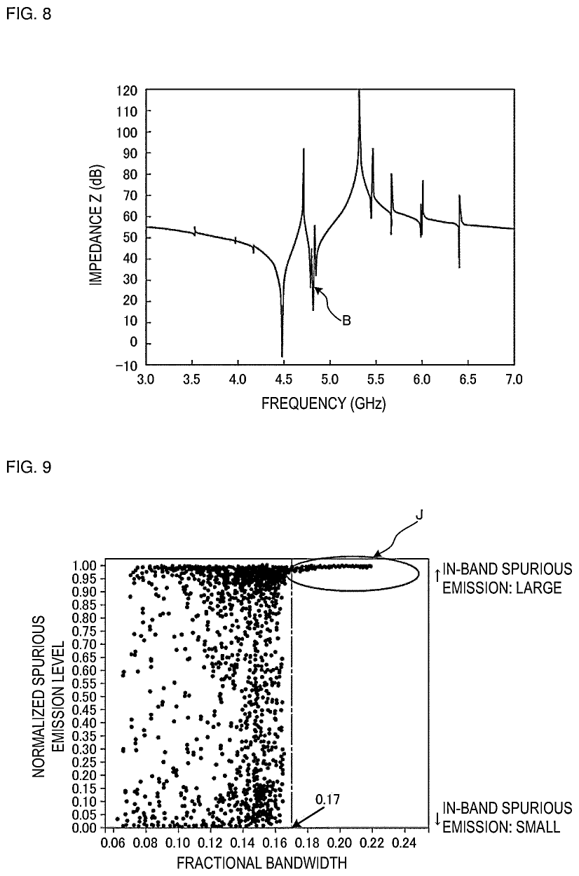

The excitation region C of the acoustic wave device 1 is a region where any adjacent electrode fingers 3 and 4 of the plurality electrode fingers 3 and 4 overlap as viewed in the direction in which the adjacent electrode fingers 3 and 4 face each other. It is preferable in the acoustic wave device 1 that MR≤about 1.75(d/p)+0.075 be satisfied, for example, where MR is a metallization ratio MR of the adjacent electrode fingers 3 and 4 to the excitation region C. Spurious emission can be effectively reduced in this case. This will be described with reference to FIG. 8 and FIG. 9.

FIG. 8 is a reference diagram illustrating an example of resonance characteristics of the acoustic wave device according to the present preferred embodiment. Arrow B indicates a spurious emission appearing between the resonant frequency and the anti-resonant frequency. In this example, d/p is about 0.08, LiNbO₃ has Euler angles (0°, 0°, 90°), and the metallization ratio MR is about 0.35, for example.

The metallization ratio MR will now be described with reference to FIG. 1B. To focus on one pair of electrode fingers 3 and 4 of the electrode structure in FIG. 1B, the description assumes that only the one pair of electrode fingers 3 and 4 is provided. In this case, a region enclosed by a dash-dot line is the excitation region C. When the electrode fingers 3 and 4 are viewed in the direction orthogonal to the length direction of the electrode fingers 3 and 4, or viewed in the direction in which the electrode fingers 3 and 4 face each other, the excitation region C includes a portion of the electrode finger 3 overlapping the electrode finger 4, a portion of the electrode finger 4 overlapping the electrode finger 3, and a portion between the electrode fingers 3 and 4 where the electrode fingers 3 and 4 face each other. The metallization ratio MR is the ratio of the area of the electrode fingers 3 and 4 in the excitation region C to the area of the excitation region C. That is, the metallization ratio MR is the ratio of the area of a metallized portion to the area of the excitation region C.

When a plurality of pairs of electrode fingers 3 and 4 are provided, MR may be the ratio of the area of metallized portions included in all excitation regions C to the sum of the areas of the excitation regions C.

FIG. 9 is an explanatory diagram illustrating a relation between the fractional bandwidth of the acoustic wave device of the present preferred embodiment, and the amount of phase rotation of impedance of spurious emission normalized at 180 degrees to represent the level of spurious emission. The fractional bandwidth is adjusted by varying the film thickness of the piezoelectric layer 2 or the dimensions of the electrode fingers 3 and 4. FIG. 9 illustrates a result of using a Z-cut LiNbO₃ layer as the piezoelectric layer 2. A similar tendency is observed when the piezoelectric layer 2 with other cut-angles is used.

In the region enclosed by oval J in FIG. 9, the level of spurious emission is as high as about 1.0, for example. As is clear from FIG. 9, when the fractional bandwidth exceeds about 0.17 or about 17%, for example, a large spurious emission with a spurious emission level of 1 or higher appears in the pass band even if parameters defining the fractional bandwidth are changed. That is, as in the resonance characteristics illustrated in FIG. 8, a large spurious emission indicated by arrow B appears in the band. Therefore, it is preferable that the fractional bandwidth be less than or equal to about 17%, for example. In this case, adjusting the film thickness of the piezoelectric layer 2 or the dimensions of the electrode fingers 3 and 4 can reduce spurious emission.

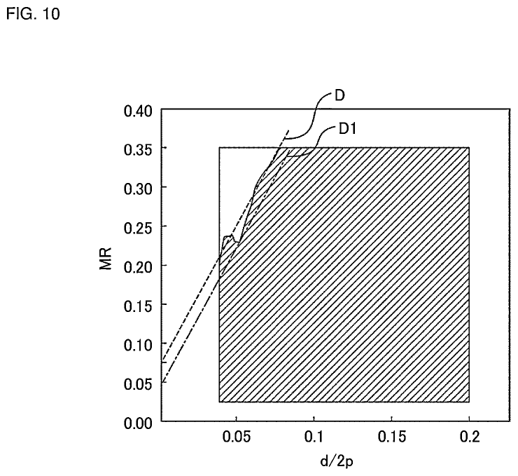

FIG. 10 is an explanatory diagram illustrating a relation between d/2p, metallization ratio MR, and fractional bandwidth. Various acoustic wave devices 1 of the present preferred embodiment are made by varying d/2p and MR to measure the fractional bandwidths. In FIG. 10, a hatched region to the right of broken line D is a region where the fractional bandwidth is less than or equal to about 17%, for example. The boundary between the hatched and non-hatched regions is represented by MR=about 3.5(d/2p)+0.075 or MR=about 1.75(d/p)+0.075, and preferably MR≤about 1.75(d/p)+0.075, for example. In this case, it is easier to make the fractional bandwidth less than or equal to about 17%, for example. A more preferable region is one that is to the right of the boundary represented by MR=about 3.5(d/2p)+0.05, for example, indicated by dash-dot line D1 in FIG. 10. That is, if MR≤about 1.75(d/p)+0.05 is satisfied, the fractional bandwidth can be reliably made less than or equal to about 17%, for example.

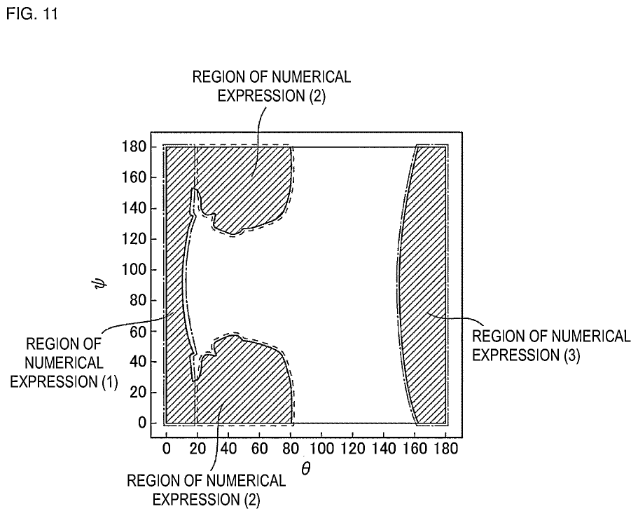

FIG. 11 is an explanatory diagram illustrating a map of fractional bandwidth with respect to Euler angles (0°, θ, Ψ) of LiNbO₃ obtained when d/p is brought as close as possible to 0. Hatched regions in FIG. 11 are regions where a fractional bandwidth of at least greater than or equal to about 5% can be obtained, for example. By approximating the ranges of these regions, ranges defined by numerical expression (1), numerical expression (2) and numerical expression (3) described below are obtained.

(0°±10°, 0° to 20°, any Ψ) numerical expression (1)

(0°±10°, 20° to 80°, 0° to 60° (1−(θ−50)²/900)^{1/2}) or (0°±10°, 20° to 80°, [180°−60° (1−(θ−50)²/900)^{1/2}] to 180°) numerical expression (2)

(0°±10°, [180°−30° (1−(Ψ−90)²/8100)^{1/2}] to 180°, any Ψ) numerical expression (3)

The ranges of the Euler angles defined by numerical expression (1), numerical expression (2), or numerical expression (3) are preferable, because a sufficiently wide fractional bandwidth can be achieved.

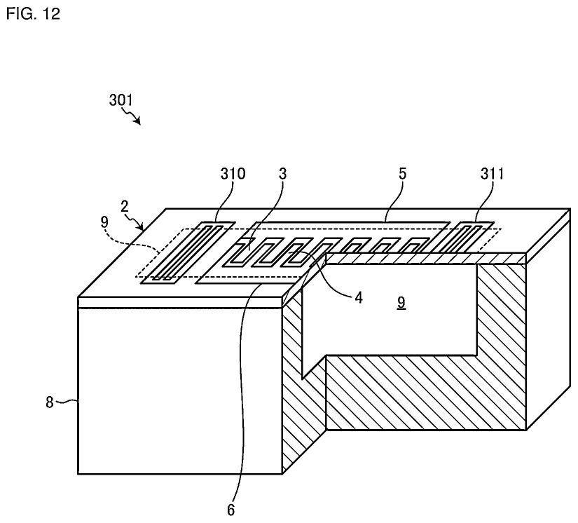

FIG. 12 is a partial cutaway perspective view for explaining an acoustic wave device according to a preferred embodiment of the present disclosure. In FIG. 12, the outer edge of the hollow 9 is indicated by a broken line. An acoustic wave device according to a preferred embodiment of the present disclosure may use plate waves, for example. In this case, an acoustic wave device 301 includes reflectors 310 and 311, as illustrated in FIG. 12. The reflectors 310 and 311 are disposed on both sides of the electrode fingers 3 and 4 on the piezoelectric layer 2 in the propagation direction of acoustic waves. In the acoustic wave device 301, Lamb waves (or plate waves) are excited by applying an alternating-current electric field to the electrode fingers 3 and 4 above the hollow 9. With the reflectors 310 and 311 on both sides, the resonance characteristics based on Lamb waves (or plate waves) can be obtained.

As described above, the acoustic wave devices 1 and 101 use first-order thickness shear mode bulk waves. In the acoustic wave devices 1 and 101, the electrode fingers 3 and 4 are adjacent electrodes and d/p is less than or equal to about 0.5, for example, where d is the thickness of the piezoelectric layer 2 and p is the center-to-center distance between the electrode fingers 3 and 4. This can improve the Q factor even when the acoustic wave device is reduced in size.

In the acoustic wave devices 1 and 101, the piezoelectric layer 2 is made of lithium niobate or lithium tantalate. The first principal surface 2a or the second principal surface 2b of the piezoelectric layer 2 has thereon the electrode fingers 3 and 4 facing each other in the direction crossing the thickness direction of the piezoelectric layer 2. The electrode fingers 3 and 4 are preferably covered with a protective film.

### First Preferred Embodiment

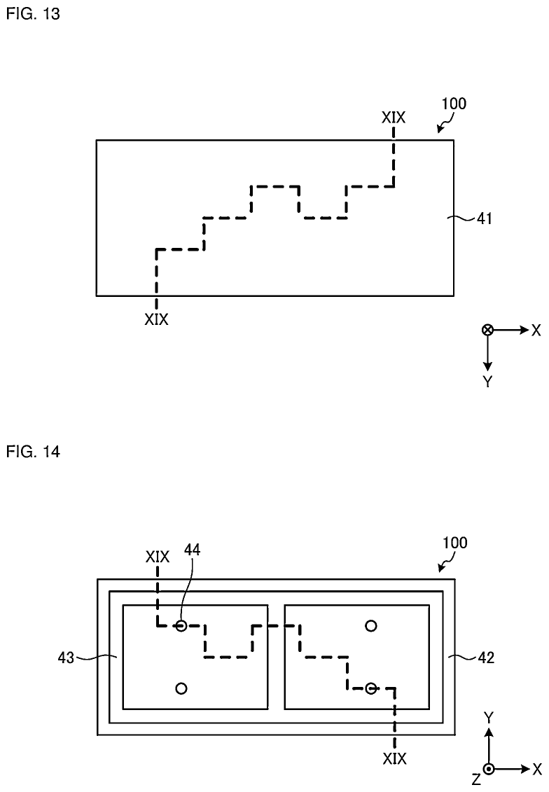

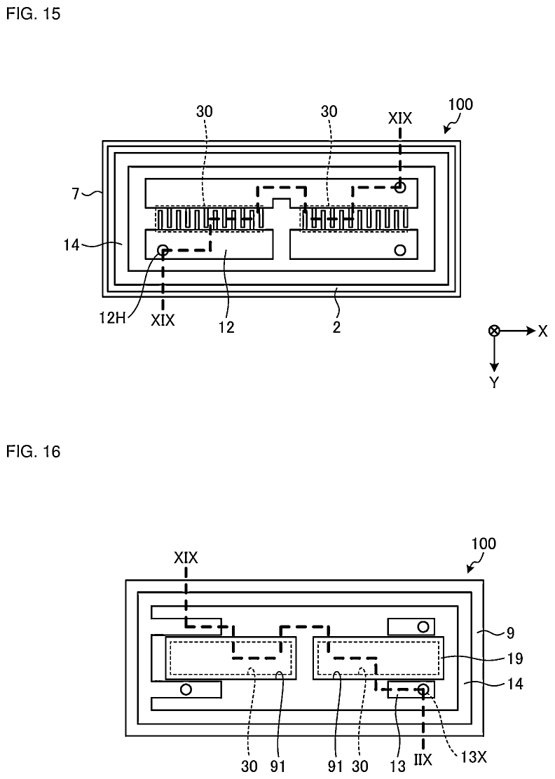

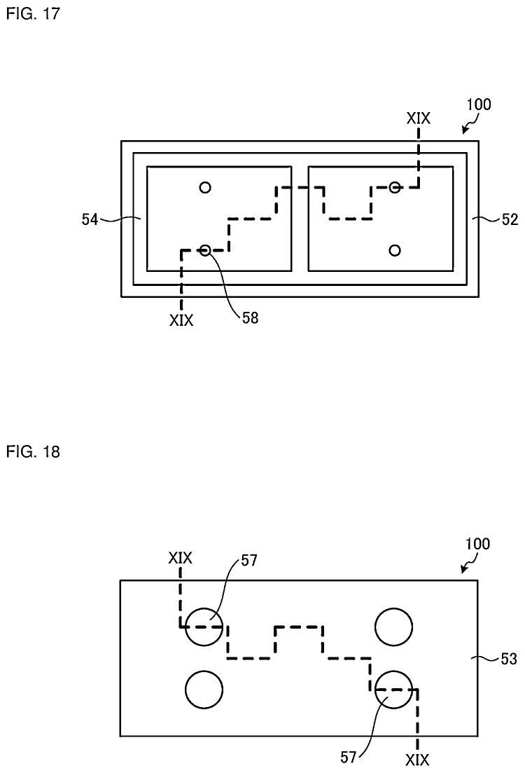

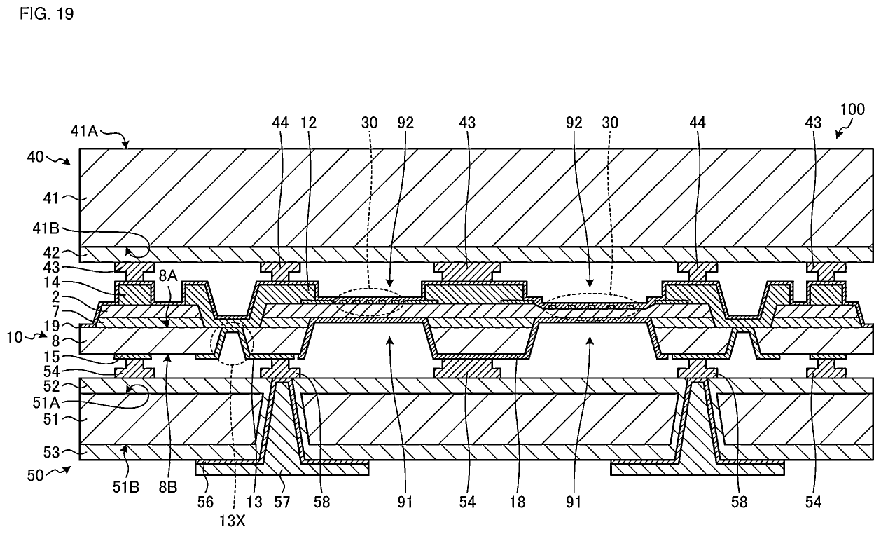

FIG. 13 is a plan view of a first cover according to a first preferred embodiment, as viewed from a first principal surface thereof. FIG. 14 is a plan view of the first cover according to the first preferred embodiment, as viewed from a second principal surface thereof. FIG. 15 is a plan view of an acoustic wave element substrate according to the first preferred embodiment, as viewed from a first principal surface thereof. FIG. 16 is a plan view of the acoustic wave element substrate according to the first preferred embodiment, as viewed from a second principal surface thereof. FIG. 17 is a plan view of a second cover according to the first preferred embodiment, as viewed from a first principal surface thereof. FIG. 18 is a plan view of the second cover according to the first preferred embodiment, as viewed from a second principal surface thereof. FIG. 19 is a schematic cross-sectional view illustrating a cross section taken along line XIX-XIX of FIG. 13 to FIG. 18.

As illustrated in FIG. 13 to FIG. 19, in an acoustic wave device 100 according to the first preferred embodiment, an acoustic wave element substrate 10 is sandwiched between a first cover 40 and a second cover 50. The functional electrode 30 illustrated in FIG. 19 is an interdigital transducer electrode (illustrated in FIG. 1B) including the first busbar electrode 5 and the second busbar electrode 6 opposite each other, the electrode fingers 3 connected to the first busbar electrode 5, and the electrode fingers 4 connected to the second busbar electrode 6.

As illustrated in FIG. 13, FIG. 14, and FIG. 19, the first cover 40 includes a second substrate 41, an insulating layer 42 covering a second principal surface 41B of the second substrate 41, and a sealing metal layer 43 and a sealing metal layer 44 disposed on the insulating layer 42. The second substrate 41 is, for example, a silicon substrate. The insulating layer 42 is of silicon oxide.

The sealing metal layer 43 and the sealing metal layer 44 each are a metal laminate of gold or gold alloy and another metal, such as titanium, and define a first support portion that allows the acoustic wave element substrate 10 to be supported by the first cover 40. The sealing metal layer 43 is formed in a linear pattern to surround the functional electrode 30 in plan view in the Z direction. The sealing metal layer 43 can hermetically seal a second hollow 92. A first principal surface 41A of the second substrate 41 may be protected by a silicon oxide layer, such as the insulating layer 42.

A sealing metal layer 44 is disposed in a dot pattern in a region surrounded by the sealing metal layer 43. The sealing metal layer 44 is made of the same material as the sealing metal layer 43 and joins the first cover 40 to the acoustic wave element substrate 10. This reduces warpage of the acoustic wave element substrate 10.

The acoustic wave element substrate 10 includes at least one functional electrode 30, and includes two functional electrodes 30 in the first preferred embodiments. The acoustic wave element substrate 10 includes the support substrate 8 and the piezoelectric layer 2 disposed adjacent to a first principal surface 8A of the support substrate 8. The piezoelectric layer 2 includes, for example, lithium niobate or lithium tantalate. The piezoelectric layer 2 may including lithium niobate or lithium tantalate and incidental impurities. In the first preferred embodiment, the piezoelectric layer 2 is disposed on the support substrate 8, with the intermediate layer 7 interposed therebetween. The intermediate layer 7 is optional. In the first preferred embodiment, the support substrate 8 and the intermediate layer 7 may be collectively referred to as a first support. The functional electrode 30 will not be described in detail here, as it has the same configuration as that illustrated in FIG. 1B.

The functional electrode 30 is electrically connected to a wiring layer 12, which is greater in thickness than the electrode fingers 3 and 4. As illustrated in FIG. 15, a joining layer 14 is a metal layer linearly disposed to surround the functional electrode 30 and the wiring layer 12 and is made of the same material as the wiring layer 12. The joining layer 14 is level with the wiring layer 12.

As illustrated in FIG. 16, the support substrate 8 includes a through electrode 13X that electrically connects the first principal surface 8A to a second principal surface 8B. The wiring layer 12 is electrically connected to an extended electrode 13 on the second principal surface 8B, with the through electrode 13X illustrated in FIG. 16 therebetween. This allows signal input from a side opposite the first principal surface 8A adjacent to the functional electrode 30.

A first hollow 91 illustrated in FIG. 19 and FIG. 16 is overlapping at least portion of the functional electrode 30 as viewed in the Z direction. The first hollow 91 is formed in a cavity of the first support by recessing the second principal surface 8B of the support substrate 8. The first hollow 91 corresponds to the hollow 9 illustrated in FIG. 2 and is disposed in the cavity of the support substrate 8. The first hollow 91 is a space between the acoustic wave element substrate 10 and the second cover 50.

The second hollow 92 illustrated in FIG. 19 is a space between the acoustic wave element substrate 10 and the first cover 40. The second hollow 92 is surrounded by the sealing metal layer 43.

As illustrated in FIG. 17, FIG. 18, and FIG. 19, the second cover 50 includes a third substrate 51, an insulating layer 52 covering a first principal surface 51A of the third substrate 51, an insulating layer 53 covering a second principal surface 51B of the third substrate 51, and a sealing metal layer 54 and a sealing metal layer 58 disposed on the insulating layer 52. The third substrate 51 is, for example, a silicon substrate. The insulating layer 52 and the insulating layer 53 are of silicon oxide.

The sealing metal layer 54 and the sealing metal layer 58 each are a metal laminate of gold or gold alloy and another metal, such as titanium, and define the second support portion that allows the acoustic wave element substrate 10 to be supported by the second cover 50. As illustrated in FIG. 17, the sealing metal layer 54 is formed in a linear pattern to surround the functional electrode 30 in plan view in the Z direction. The sealing metal layer 54 can thus hermetically seal the first hollow 91.

A through via penetrating the third substrate 51 from the first principal surface 51A to the second principal surface 51B is coated with a seed layer 56 and has a terminal electrode 57 on the seed layer 56. The seed layer 56 is a multilayer body including a Ti layer and a Cu layer thereon. The terminal electrode 57 is a multilayer body including a Cu layer and an Ni layer plated with an Au layer. The terminal electrode 57 is also called an under bump metal and has thereon, for example, a ball grid array (BGA) bump (not shown).

As described above, the acoustic wave device 100 according to the first preferred embodiment includes the support substrate 8 (first substrate) having a thickness in the Z direction, the piezoelectric layer 2 adjacent to the first principal surface 8A of the support substrate 8, the functional electrode 30 on the piezoelectric layer 2, the second substrate 41, and the third substrate 51. The support substrate 8 has the first hollow 91 overlapping at least a portion of the functional electrode 30 as viewed in the Z direction. The second substrate 41 faces the support substrate 8, with the second hollow 92 therebetween. The third substrate 51 faces the support substrate 8, with the first hollow 91 therebetween. The acoustic wave device 100 includes the first support portion disposed between the first principal surface 8A of the support substrate 8 and the second substrate 41, and the second support portion disposed between the support substrate 8 and the third substrate 51. The first support portion includes the joining layer 14, the sealing metal layer 43, and the sealing metal layer 44. The second support portion includes a joining layer 15, the sealing metal layer 54, and the sealing metal layer 58.

Thus, even when the support substrate 8 (first substrate) is made thinner, degradation of the mechanical strength of the support substrate 8 is reduced, as the support substrate 8 is supported on both sides by the second substrate 41 and the third substrate 51. The first support portion hermetically seals the second hollow between the piezoelectric layer and the second substrate and joins the piezoelectric layer to the second substrate. The second support portion hermetically seals the first hollow between the first substrate and the third substrate and joins the first substrate to the third substrate.

The functional electrode 30 is disposed in each of a plurality of regions on the piezoelectric layer 2, and a dielectric film 18 varies in thickness from one region to another. This can change the resonant frequency required for each functional electrode 30. The dielectric film 18 is of, for example, silicon oxide.

The first support portion and the second support portion are multilayer bodies each including metal. This improves the performance of sealing the first hollow 91 and the second hollow 92.

The support substrate 8 and the piezoelectric layer 2 can be joined by sandwiching the intermediate layer 7 therebetween.

The support substrate 8 (first substrate), the second substrate 41, and the third substrate 51 are silicon substrates. A wafer level package is thus produced.

In the first preferred embodiment, the dielectric film 18 is disposed on the surface of the piezoelectric layer 2 opposite the functional electrode 30. Therefore, adjusting the film thickness of the dielectric film 18 for the purpose of frequency adjustment is less likely to cause process damage to the functional electrode 30.

In a preferred embodiment, the thickness of the piezoelectric layer 2 is less than or equal to 2p, where p is a center-to-center distance between adjacent electrode fingers 3 and 4 of the plurality of electrode fingers 3 and the plurality of electrode fingers 4. This can reduce the size of the acoustic wave device 1 and improve the Q factor.

In a more preferred embodiment, the piezoelectric layer 2 includes lithium niobate or lithium tantalate. This makes it possible to provide an acoustic wave device having good resonance characteristics.

In a still more preferred embodiment, Euler angles (φ, θ, Ψ) of lithium niobate or lithium tantalate forming the piezoelectric layer 2 are in the range defined by numerical expression (1), numerical expression (2), or numerical expression (3) described below. This can sufficiently widen the fractional bandwidth.

(0°±10°, 0° to 20°, any Ψ) numerical expression (1)

(0°±10°, 20° to 80°, 0° to 60° (1−(θ−50)²/900)^{1/2}) or (0°±10°, 20° to 80°, [180°−60° (1−(θ−50)²/900)^{1/2}] to 180°) numerical expression (2)

(0°±10°, [180°−30° (1−(Ψ−90)²/8100)^{1/2}] to 180°, any Ψ) numerical expression (3)

In a preferred embodiment, the acoustic wave device 1 is configured to be capable of using thickness shear mode bulk waves. This improves the coupling coefficient and makes it possible to provide an acoustic wave device having good resonance characteristics.

In a more preferred embodiment, d/p about 0.5 is satisfied, for example, where d is the thickness of the piezoelectric layer 2 and p is the center-to-center distance between adjacent electrode fingers 3 and 4. This can reduce the size of the acoustic wave device 1 and improve the Q factor.

In a still more preferred embodiment, d/p is less than or equal to about 0.24, for example. This can reduce the size of the acoustic wave device 1 and improve the Q factor.

In a preferred embodiment, when a region where adjacent electrode fingers 3 and 4 overlap in a direction in which the adjacent electrode fingers 3 and 4 face each other is the excitation region C, MR≤about 1.75(d/p)+0.075 is satisfied, where MR is the metallization ratio of the plurality of electrode fingers 3 and the plurality of electrode fingers 4 to the excitation region C. This can reliably make the fractional bandwidth less than or equal to about 17%, for example.

In a preferred embodiment, the acoustic wave device 301 may be configured to be capable of using plate waves. This makes it possible to provide an acoustic wave device having good resonance characteristics.

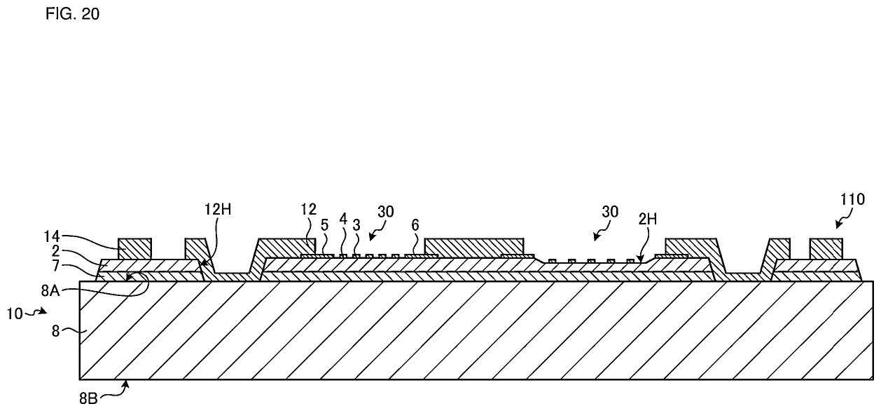

FIG. 20 is a schematic cross-sectional view for explaining a support forming step of forming an acoustic wave element substrate according to the first preferred embodiment. As illustrated in FIG. 20, the intermediate layer 7 is placed on the support substrate 8. The piezoelectric layer 2 is joined to the support substrate 8, with the intermediate layer 7 therebetween. Next, the electrode fingers 3, the electrode fingers 4, and the first busbar electrode 5 and the second busbar electrode 6 are formed on the piezoelectric layer 2. When the functional electrode 30 is placed in each of a plurality of regions on the piezoelectric layer 2, a recess 2H of the piezoelectric layer 2 may be formed for each functional electrode 30 to adjust the thickness of the piezoelectric body. Next, the piezoelectric layer 2 is partially covered with a resist and a region not covered with the resist is etched. This is followed by forming the joining layer 14 and the wiring layer 12. The wiring layer 12 is placed over the etched region of the piezoelectric layer 2 to form a through hole 12H (see FIG. 15).

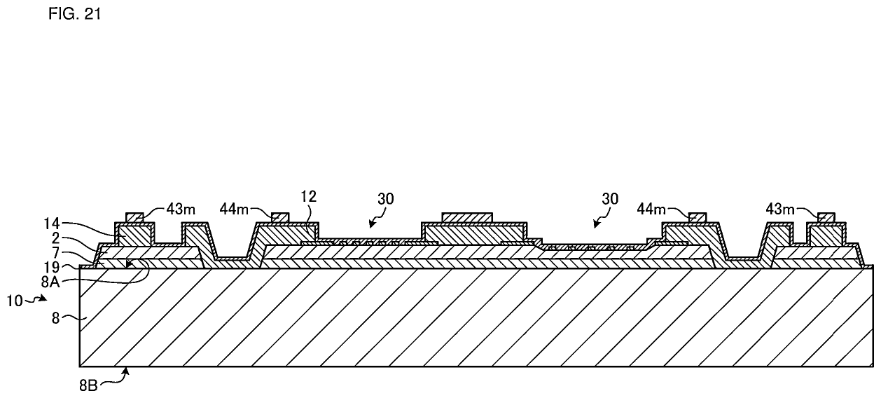

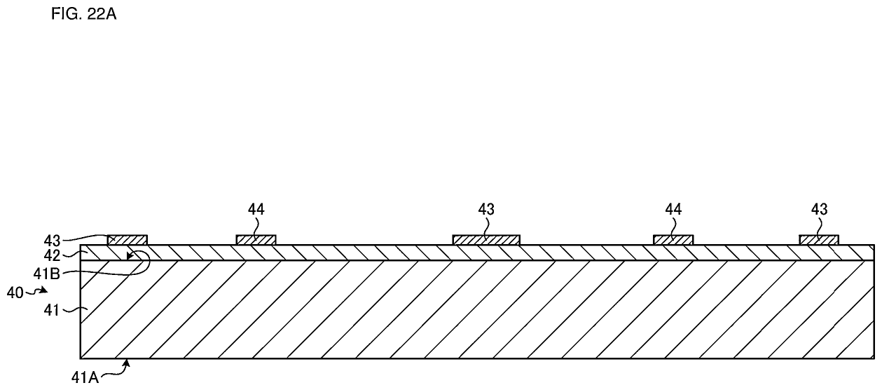

FIG. 21 is a schematic cross-sectional view for explaining a dielectric film forming step of forming a dielectric film on the acoustic wave element substrate according to the first preferred embodiment. As illustrated in FIG. 21, a dielectric film 19 is deposited on the first principal surface 8A of the support substrate 8, the piezoelectric layer 2, the joining layer 14, and the wiring layer 12. The dielectric film 19 is of silicon oxide. Next, a sealing metal layer 43m and a sealing metal layer 44m are formed at positions that overlap portions of the joining layer 14 and the wiring layer 12. The sealing metal layer 43m and the sealing metal layer 44m are made of the same material as the sealing metal layer 43 and the sealing metal layer 44. The acoustic wave element substrate 10 is thus prepared by the steps described above.

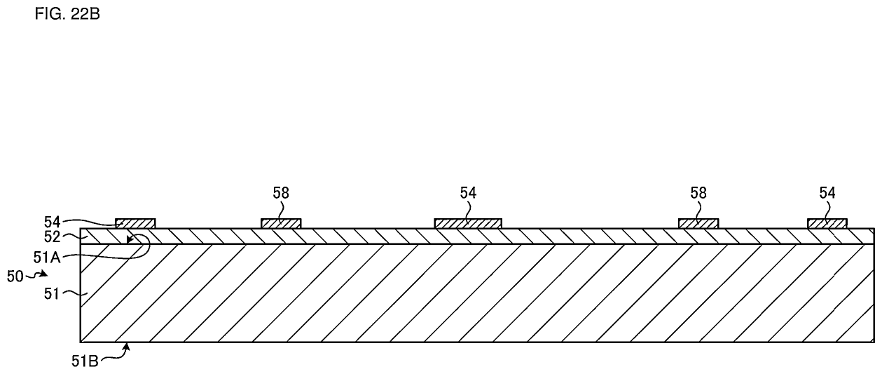

FIG. 22A is a schematic cross-sectional view for explaining a first cover forming step of forming a first cover according to the first preferred embodiment. In the first cover forming step, the insulating layer 42 is formed on a second principal surface 41B of the second substrate 41. The sealing metal layer 43 is formed on the insulating layer 42.

FIG. 22B is a schematic cross-sectional view for explaining a second cover forming step of forming a second cover according to the first preferred embodiment. In the second cover forming step, the insulating layer 52 is formed on the first principal surface 51A of the third substrate 51. The sealing metal layer 54 is formed on the insulating layer 52.

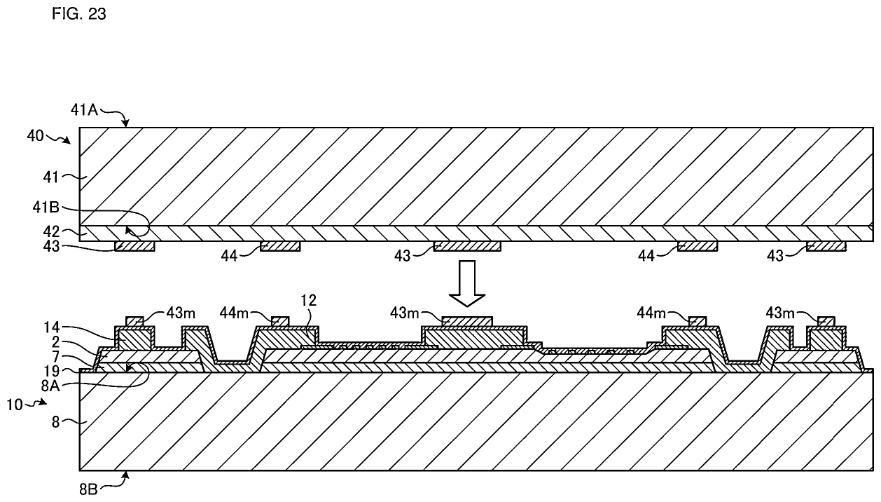

FIG. 23 is a schematic cross-sectional view for explaining a first joining step of joining the first cover to the acoustic wave element substrate. As illustrated in FIG. 23, the first cover 40 is placed opposite the acoustic wave element substrate 10 and joined to the acoustic wave element substrate 10. Specifically, the sealing metal layer 43m of the acoustic wave element substrate 10 and the sealing metal layer 43 of the first cover 40 are joined by Au—Au bonding to integrate the sealing metal layer 43m into the sealing metal layer 43. The sealing metal layer 44m of the acoustic wave element substrate 10 and the sealing metal layer 44 of the first cover 40 are joined by Au—Au bonding to integrate the sealing metal layer 44m into the sealing metal layer 44.

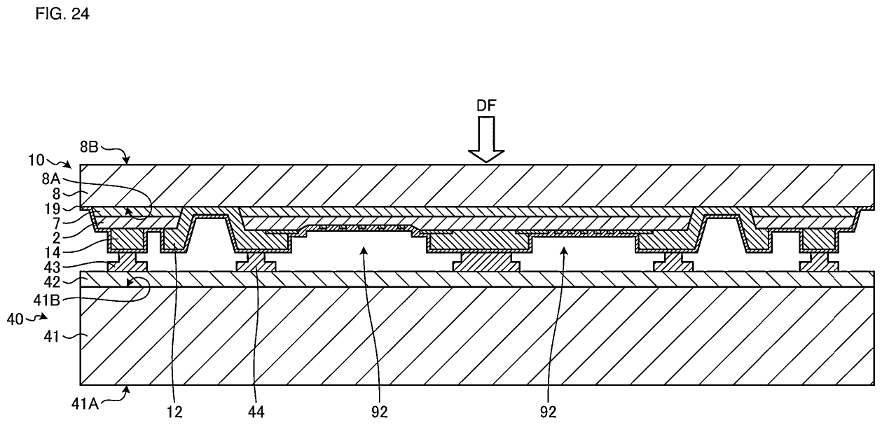

FIG. 24 is a schematic cross-sectional view for explaining a thinning step of making a first substrate thinner according to the first preferred embodiment. As illustrated in FIG. 24, the thinning step grinds the second principal surface 8B of the support substrate 8 with a grinding tool DF to make the support substrate 8 thinner.

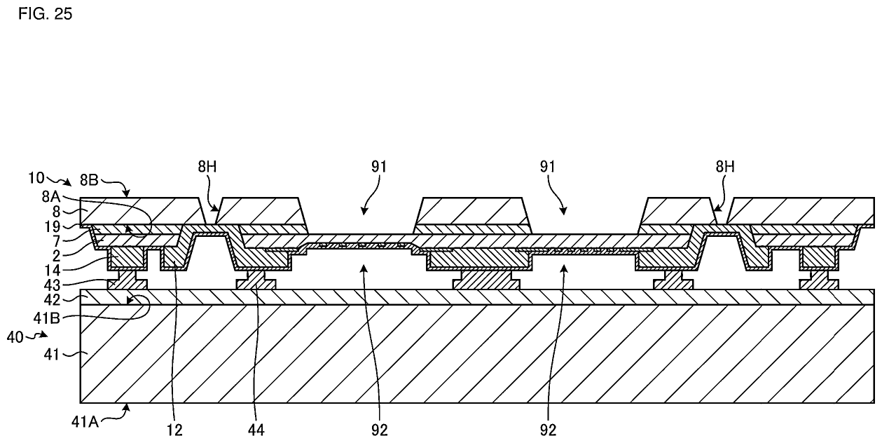

FIG. 25 is a schematic cross-sectional view for explaining a first hollow forming step of forming a first hollow in the first substrate according to the first preferred embodiment. As illustrated in FIG. 25, the first hollow forming step etches the support substrate 8 from the second principal surface 8B of the support substrate 8 in such a way as to expose the piezoelectric layer 2 to the first hollow 91. The first hollow forming step also etches the support substrate 8 from the second principal surface 8B of the support substrate 8 to form a recess 8H that exposes the wiring layer 12. Etching in the first hollow forming step uses such a technique as dry etching or reactive ion etching.

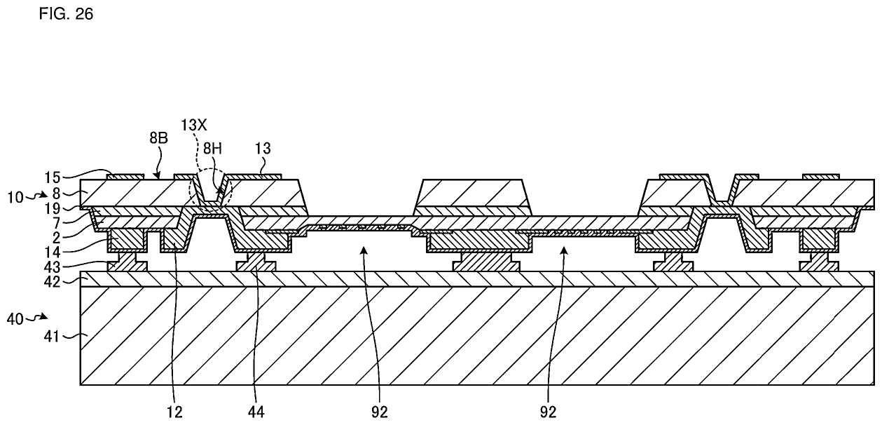

FIG. 26 is a schematic cross-sectional view for explaining a wire forming step of forming an extended electrode on the second principal surface of the first substrate according to the first preferred embodiment. As illustrated in FIG. 26, the extended electrode 13 is formed in the recess 8H as well as on the second principal surface 8B of the support substrate 8. The recess 8H is formed in an area not overlapping the functional electrode 30, as viewed in the Z direction. The through electrode 13X that electrically connects the first principal surface 8A to the second principal surface 8B is thus formed in the support substrate 8. The joining layer 15 is formed on the second principal surface 8B of the support substrate 8.

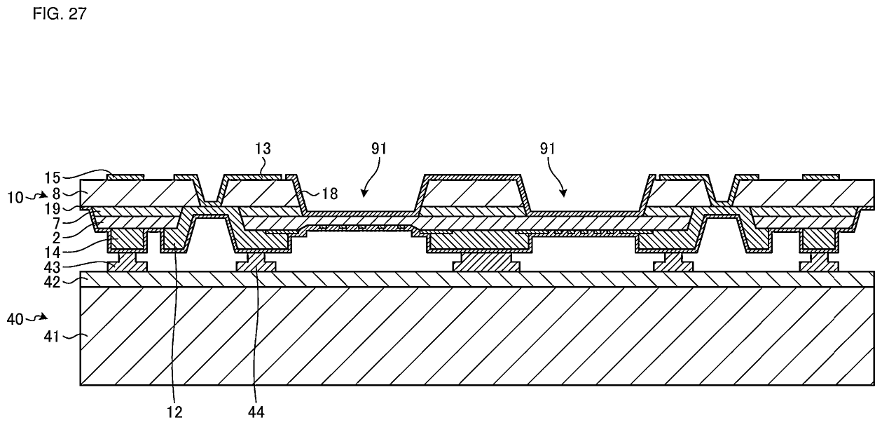

FIG. 27 is a schematic cross-sectional view for explaining a wire forming step of forming a dielectric film on the second principal surface of the first substrate according to the first preferred embodiment. As illustrated in FIG. 27, an area except the first hollow 91 is masked with a resist to form the dielectric film 18. The resist is then removed. The piezoelectric layer 2 in the first hollow 91 is covered with the dielectric film 18.

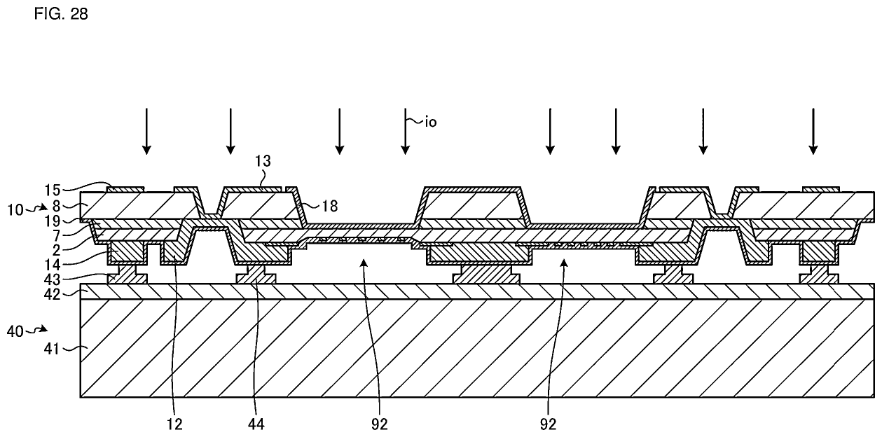

FIG. 28 is a schematic cross-sectional view for explaining a frequency adjusting step of adjusting the frequency of the acoustic wave device according to the first preferred embodiment. After a measuring device is connected to the extended electrode 13 to check the frequency characteristics, the film thickness of the dielectric film 18 is adjusted, for example, by ion etching io. The film thickness of the dielectric film 18 is adjusted until desired frequency characteristics are achieved. The ion etching io is repeated until desired frequency characteristics are achieved.

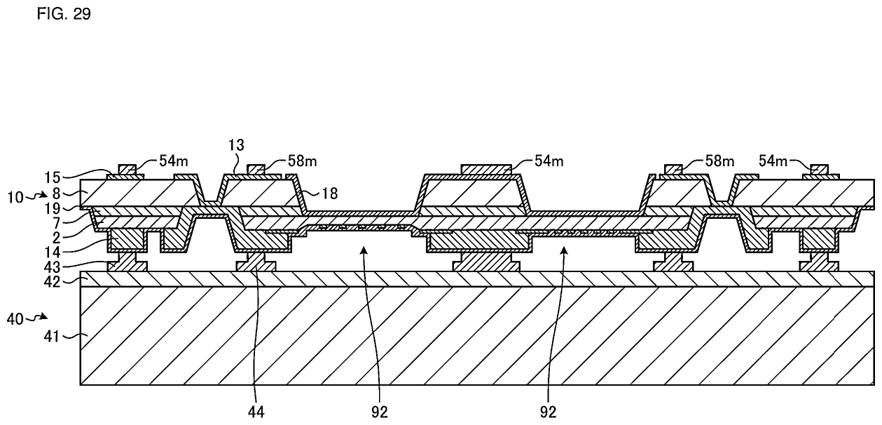

FIG. 29 is a schematic cross-sectional view for explaining a joint metal forming step of forming a joining layer on the second principal surface of the first substrate according to the first preferred embodiment. As illustrated in FIG. 29, a sealing metal layer 54m and a sealing metal layer 58m are formed at positions that overlap portions of the joining layer 15 and the extended electrode 13. The sealing metal layer 54m and the sealing metal layer 58m are made of the same material as the sealing metal layer 54 and the sealing metal layer 58.

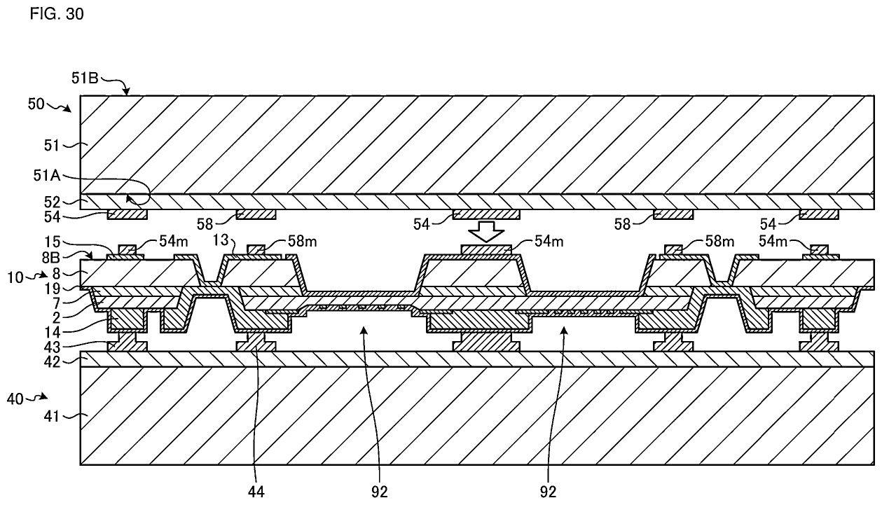

FIG. 30 is a schematic cross-sectional view for explaining a second joining step of joining the second cover to the acoustic wave element substrate. As illustrated in FIG. 30, the second cover 50 is placed opposite the acoustic wave element substrate 10 and joined to the acoustic wave element substrate 10. Specifically, the sealing metal layer 54m of the acoustic wave element substrate 10 and the sealing metal layer 54 of the second cover 50 are joined by Au—Au bonding to integrate the sealing metal layer 54m into the sealing metal layer 54. The sealing metal layer 58m of the acoustic wave element substrate 10 and the sealing metal layer 58 of the second cover 50 are joined by Au—Au bonding to integrate the sealing metal layer 58m into the sealing metal layer 58.

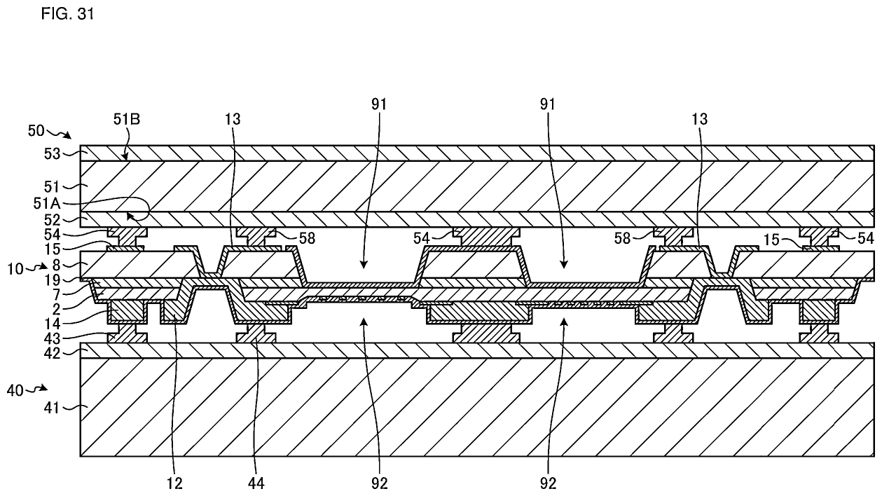

FIG. 31 is a schematic cross-sectional view for explaining a thinning step of making a third substrate thinner according to the first preferred embodiment. The thinning step grinds the second principal surface 51B of the third substrate 51 with a grinding tool to make the third substrate 51 thinner. The grinding is followed by forming the insulating layer 53 to cover the second principal surface 51B of the third substrate 51.

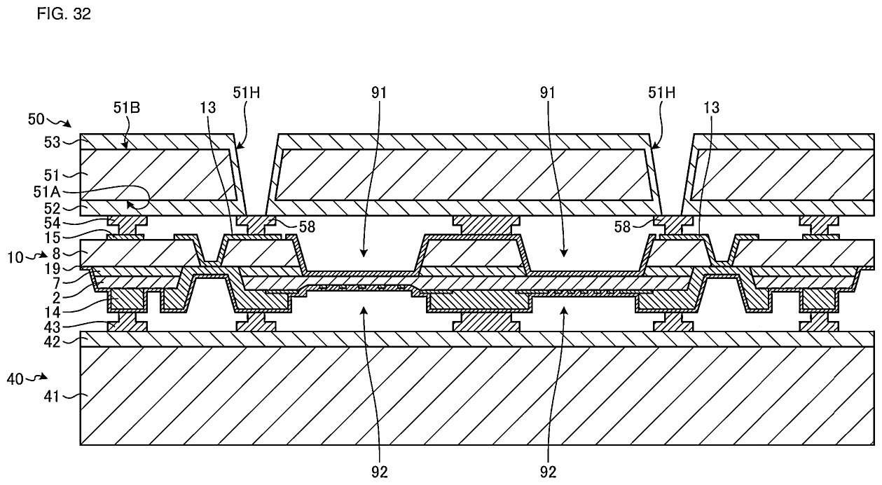

FIG. 32 is a schematic cross-sectional view for explaining a through via forming step of forming a through via in the third substrate according to the first preferred embodiment. As illustrated in FIG. 32, a through via 51H is formed by dry etching or reactive ion etching.

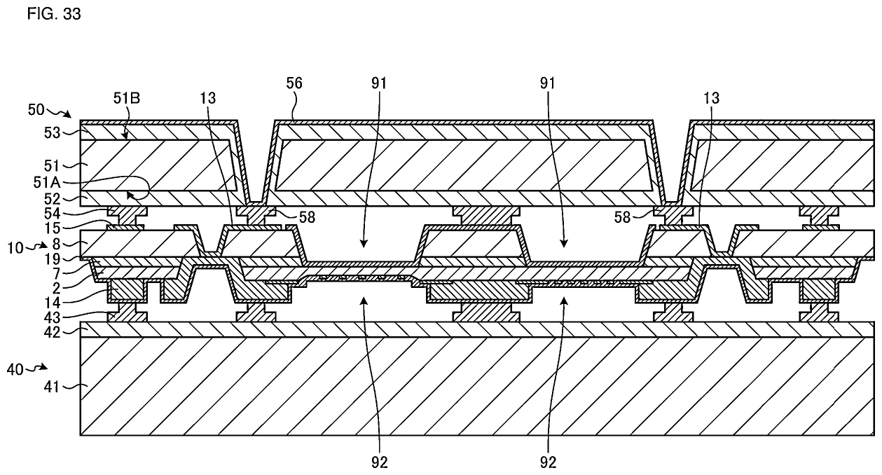

FIG. 33 is a schematic cross-sectional view for explaining a seed metal layer forming step of forming a seed metal layer adjacent to the second principal surface of the third substrate according to the first preferred embodiment. As illustrated in FIG. 33, the seed layer 56 is formed to cover the through via 51H illustrated in FIG. 32. The seed layer 56 is made by forming a Ti layer and a Cu layer on the Ti layer.

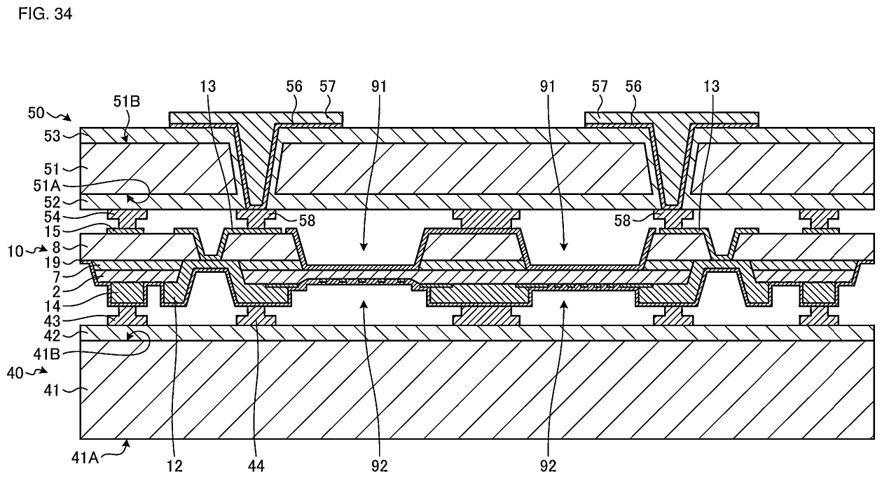

FIG. 34 is a schematic cross-sectional view for explaining a terminal electrode forming step of forming a terminal electrode adjacent to the second principal surface of the third substrate according to the first preferred embodiment. As illustrated in FIG. 34, after the seed layer 56 is patterned in a region where the terminal electrode 57 is to be formed, the seed layer 56 is plated with a Cu layer, an Ni layer, and an Au layer in sequence.

As described above, the method for manufacturing an acoustic wave device includes the support forming step, the first joining step, and the thinning step. The support forming step forms the support including the support substrate 8 having a thickness in the Z direction and having the first principal surface 8A and the second principal surface 8B opposite the first principal surface 8A, the piezoelectric layer 2 disposed adjacent to the first principal surface 8A of the support substrate 8, and the functional electrode 30 disposed on the piezoelectric layer 2. After the support forming step, the first joining step places the second substrate 41 opposite the first principal surface 8A of the support substrate 8, with the second hollow 92 therebetween, and joins the second substrate 41 to the support substrate 8, with the sealing metal layer 43 and the sealing metal layer 44 therebetween. After the first joining step, the thinning step makes the support substrate 8 thinner.

The support substrate 8 is thus made thinner while being supported by the second substrate 41. This allows the support substrate 8 to be processed at a wafer level and makes it less likely that the support substrate 8 will be damaged.

The method for manufacturing an acoustic wave device further includes the first hollow forming step. After the thinning step, the first hollow forming step forms the first hollow 91 by making a hole from the second principal surface 8B of the support substrate 8 until the piezoelectric layer 2 is exposed. The first hollow can thus be processed at a wafer level and a plurality of first hollows 91 can be formed easily.

The method for manufacturing an acoustic wave device further includes the frequency adjusting step. After the first hollow forming step, the frequency adjusting step forms the dielectric film 18 on the piezoelectric layer 2 exposed to the first hollow 91 and adjusts the film thickness of the dielectric film 18. The dielectric film 18 on the surface of the piezoelectric layer 2 opposite the functional electrode 30 can thus be adjusted. This is less likely to cause process damage to the functional electrode 30.

The method for manufacturing an acoustic wave device further includes the second joining step. After the frequency adjusting step, the second joining step places the third substrate 51 adjacent to the second principal surface 8B of the support substrate 8, with the first hollow 91 therebetween, and joins the third substrate 51 to the support substrate 8, with the sealing metal layer 54 and the sealing metal layer 58 therebetween. Thus, even when the support substrate 8 is made thinner, degradation of the mechanical strength of the support substrate 8 can be reduced, as the support substrate 8 is supported on both sides by the second substrate 41 and the third substrate 51.

The preferred embodiments described above are presented to facilitate understanding of the present disclosure, and are not intended to limit interpretation of the present disclosure. The present disclosure can be changed or modified without departing from the spirit of the present disclosure, and the present disclosure also includes equivalents thereof.

For example, the present disclosure is also applicable to a preferred embodiment where the functional electrode 30 includes upper and lower electrodes by which the piezoelectric layer 2 is sandwiched therebetween in the thickness direction. Such an acoustic wave device may also be called a bulk acoustic wave element (BAW element).

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a first substrate with a thickness in a first direction and including a first principal surface and a second principal surface opposite the first principal surface;
a piezoelectric layer adjacent to the first principal surface of the first substrate;
a functional electrode on the piezoelectric layer;
a first hollow of the first substrate overlapping at least portion of the functional electrode as viewed in the first direction;
a second substrate adjacent to the first principal surface of the first substrate and facing the first substrate with a second hollow interposed therebetween;
a first support portion between the first principal surface of the first substrate and the second substrate;
a third substrate adjacent to the second principal surface of the first substrate and facing the first substrate with the first hollow interposed therebetween; and
a second support portion between the first substrate and the third substrate.

2. The acoustic wave device according to claim 1, further comprising a dielectric film on a surface of the piezoelectric layer opposite the functional electrode.

3. The acoustic wave device according to claim 2, wherein the functional electrode is located in each of a plurality of regions on the piezoelectric layer, and the dielectric film varies in thickness from one region to another.

4. The acoustic wave device according to claim 1, wherein the first support portion and the second support portion include metal.

5. The acoustic wave device according to claim 1, wherein the first substrate, the second substrate, and the third substrate are silicon substrates.

6. The acoustic wave device according to claim 1, further comprising an intermediate layer between the first substrate and the piezoelectric layer.

7. The acoustic wave device according to claim 1, wherein the first substrate includes a through electrode to electrically connect the first principal surface to the second principal surface.

8. The acoustic wave device according to claim 1, wherein the first support portion includes a sealing metal layer to seal the second hollow, and the second support portion includes a sealing metal layer to seal the first hollow.

9. The acoustic wave device according to claim 1, wherein the functional electrode includes one or more first electrode fingers extending in a second direction crossing the first direction, and one or more second electrode fingers extending in the second direction and facing at least one of the one or more first electrode fingers in a third direction orthogonal to the second direction.

10. The acoustic wave device according to claim 9, wherein a thickness of the piezoelectric layer is less than or equal to 2p, where p is a center-to-center distance between adjacent first and second electrode fingers of the one or more first electrode fingers and the one or more second electrode fingers.

11. The acoustic wave device according to claim 9, wherein the piezoelectric layer includes lithium niobate or lithium tantalate.

12. The acoustic wave device according to claim 9, wherein the acoustic wave device is structured to generate thickness shear mode bulk waves.

13. The acoustic wave device according to claim 9, wherein d/p≤about 0.5 is satisfied, where d is a thickness of the piezoelectric layer and p is a center-to-center distance between adjacent first and second electrode fingers of the one or more first electrode fingers and the one or more second electrode fingers.

14. The acoustic wave device according to claim 13, wherein d/p is less than or equal to about 0.24.

15. The acoustic wave device according to claim 1, wherein the functional electrode includes one or more first electrode fingers extending in a second direction crossing the first direction and one or more second electrode fingers extending in the second direction and facing at least one of the one or more first electrode fingers in a third direction orthogonal to the second direction, and when a region where adjacent first and second electrode fingers overlap as viewed in a direction in which the adjacent first and second electrode fingers face each other is an excitation region, MR≤about 1.75(d/p)+0.075 is satisfied, where MR is a metallization ratio of the one or more first electrode fingers and the one or more second electrode fingers to the excitation region.

16. The acoustic wave device according to claim 1, wherein the acoustic wave device is structured to generate plate waves.

17. The acoustic wave device according to claim 11, wherein Euler angles (φ, θ, Ψ) of the lithium niobate or lithium tantalate are in a range defined by numerical expression (1), numerical expression (2) or numerical expression (3):
(0°±10°, 0° to 20°, any Ψ) numerical expression (1)
(0°±10°, 20° to 80°, 0° to 60° (1−(θ−50)²/900)^{1/2}) or (0°±10°, 20° to 80°, [180°−60° (1−(θ−50)²/900)^{1/2}] to 180°) numerical expression (2)
(0°±10°, [180°−30° (1−(Ψ−90)²/8100)^{1/2}] to 180°, any Ψ) numerical expression (3).

18. A method for manufacturing an acoustic wave device, the method comprising:
a support forming step of forming a support including a first substrate with a thickness in a first direction and including a first principal surface and a second principal surface opposite the first principal surface, a piezoelectric layer adjacent to the first principal surface of the first substrate, and a functional electrode on the piezoelectric layer;
a first joining step of, after the support forming step, placing a second substrate adjacent to the first principal surface of the first substrate, with a second hollow therebetween, and joining the second substrate to the support, with a first support portion therebetween; and
a thinning step of, after the first joining step, making the first substrate thinner.

19. The method for manufacturing an acoustic wave device according to claim 18, further comprising a first hollow forming step of, after the thinning step, forming a first hollow by making a hole from the second principal surface of the first substrate until the piezoelectric layer is exposed.

20. The method for manufacturing an acoustic wave device according to claim 19, further comprising a frequency adjusting step of, after the first hollow forming step, forming a dielectric film on the piezoelectric layer exposed to the first hollow and adjusting a film thickness of the dielectric film.

21. The method for manufacturing an acoustic wave device according to claim 20, further comprising a second joining step of, after the frequency adjusting step, placing a third substrate adjacent to the second principal surface of the first substrate, with the first hollow therebetween, and joining the third substrate to the support, with a second support portion therebetween.
